(19) United States
(12) Patent Application Publication
(10) Pub. No.: US 2019/0207037 A1
(43) Pub. Date: Jul. 4, 2019

(54) THIN FILM TRANSISTOR, MANUFACTURING METHOD THEREOF, ARRAY SUBSTRATE AND DISPLAY PANEL

(71) Applicants: HEFEI BOE OPTOELECTRONICS TECHNOLOGY CO., LTD., Hefei, Anhui (CN); BOE TECHNOLOGY GROUP CO., LTD., Beijing (CN)

(72) Inventors: Chengcheng WANG, Beijing (CN); Hefei LI, Beijing (CN); Kui GONG, Beijing (CN); Biliang DONG, Beijing (CN)

(73) Assignees: HEFEI BOE OPTOELECTRONICS TECHNOLOGY CO., LTD., Heifei, Anhui (CN); BOE TECHNOLOGY GROUP CO., LTD., Beijing (CN)

(21) Appl. No.: 16/326,775

(22) PCT Filed: May 11, 2018
(86) PCT No.: PCT/CN2018/086513

§ 371 Date: Feb. 20, 2019

(30) Foreign Application Priority Data
May 15, 2017 (CN) 201710338853.X

(51) Int. Cl. H01L 29/786; H01L 21/28; H01L 29/66; H01L 21/3213; H01L 29/423

(52) U.S. Cl. CPC H01L 29/78633; H01L 29/78696; H01L 21/28123; H01L 29/42384; H01L 29/66742; H01L 21/32139; H01L 21/28114

(57) ABSTRACT

The present disclosure provides a thin film transistor, a manufacturing method thereof, an array substrate and a display panel. The thin film transistor includes a light shielding layer disposed on a base substrate, and an active layer disposed on the light shielding layer. The light shielding layer is provided with a groove on a side facing the active layer, and an orthographic projection of the active layer on the base substrate is located within an orthographic projection of a bottom surface of the groove on the base substrate.

### RELATED APPLICATION

The present application claims the benefit of Chinese Patent Application No. 201710338853.X, filed on May 15, 2017, the entire disclosure of which is incorporated herein by reference.

### FIELD

The present disclosure relates to the field of semiconductor technologies, and in particular to a thin film transistor, a manufacturing method thereof, an array substrate and a display panel.

### BACKGROUND

At present, flat panel displays (FPDs) have become mainstream products on the market, and there are more and more types of flat panel displays, such as liquid crystal displays (LCDs), organic light emitting diode (OLED) displays, plasma display panels (PDPs), field emission displays (FEDs), and the like.

Meanwhile, thin film transistor (TFT) backplane technology, which is the core technology of the FPD industry, is undergoing profound changes. However, crosstalk and splash screen have always been stubborn defects with flat panel displays. One of the main reasons is that a leakage current is too large when the thin film transistor is in a turn-off state. The leakage current mainly comes from hole current in a channel and a leakage current generated by illumination.

### SUMMARY

An aspect of the present disclosure provides a thin film transistor comprising: a light shielding layer disposed on a base substrate; and an active layer disposed on the light shielding layer. The light shielding layer is provided with a groove on a side facing the active layer, and an orthographic projection of the active layer on the base substrate is located within an orthographic projection of a bottom surface of the groove on the base substrate.

According to some embodiments of the present disclosure, the light shielding layer is a gate, and the thin film transistor further comprises: a gate insulating layer disposed between the light shielding layer and the active layer; and a source and a drain disposed on the active layer.

According to some embodiments of the present disclosure, the thin film transistor further comprises: a passivation layer disposed between the light shielding layer and the active layer; a gate insulating layer disposed on the active layer; a gate disposed on the gate insulating layer; an interlayer insulating layer disposed on the gate; and a source and a drain disposed on the interlayer insulating layer. The source is connected to the active layer through a first via hole, and the drain is connected to the active layer through a second via hole.

According to some embodiments of the present disclosure, the groove has an opening depth of from 1000 Å to 10000 Å.

According to some embodiments of the present disclosure, the light shielding layer is a metal, and the groove has an opening depth of 1700 Å.

According to some embodiments of the present disclosure, the light shielding layer is made of a black matrix material, and the groove has an opening depth of 5000 Å to 7500 Å.

According to some embodiments of the present disclosure, an angle between an inner sidewall of the groove and a bottom of the groove is not less than 90°.

Another aspect of the present disclosure provides an array substrate comprising any of the thin film transistors described above.

A further aspect of the present disclosure provides a display panel comprising a backlight, and any of the array substrates described above, wherein the array substrate is disposed on a light exit side of the backlight.

Yet another aspect of the present disclosure provides a manufacturing method of a thin film transistor, comprising: forming a light shielding layer having a groove on a base substrate; and forming an active layer on the light shielding layer. An orthographic projection of the active layer on the base substrate is within an orthographic projection of a bottom surface of the groove on the base substrate.

According to some embodiments of the present disclosure, said forming a light shielding layer having a groove on a base substrate comprises: forming a first film layer on the base substrate; forming, on the first film layer, a patterned photoresist layer having regions of different thicknesses by means of a halftone mask. The patterned photoresist layer includes a first region and a second region, the second region has a thickness smaller than that of the first region, and the orthographic projection of the bottom surface of the groove on the base substrate completely overlaps an orthographic projection of the second region on the base substrate. Said forming a light shielding layer having a groove on a base substrate further comprises: removing a portion of the first film layer that is not covered by the patterned photoresist layer; removing the photoresist layer in the second region; thinning a portion of the first film layer corresponding to the second region; removing a remaining photoresist layer.

According to some embodiments of the present disclosure, said thinning a portion of the first film layer corresponding to the second region comprises: etching the portion of the first film layer corresponding to the second region for a preset duration so that a thickness of the portion of the first film layer corresponding to the second region is halved.

### BRIEF DESCRIPTION OF THE DRAWINGS

FIG. 1 is a schematic structural view of a typical thin film transistor;

FIG. 2 is a schematic structural view of a bottom gate type thin film transistor provided by an embodiment of the present disclosure;

FIG. 3 is a schematic structural view of a top gate type thin film transistor provided by an embodiment of the present disclosure;

FIG. 4 is a schematic structural view of a bottom gate type thin film transistor provided by an embodiment of the present disclosure in which a top area of the groove is larger than a bottom area thereof;

FIG. 5 is a flow chart of manufacturing a bottom gate type thin film transistor provided by an embodiment of the present disclosure;

FIG. 6 is a schematic view illustrating that a photoresist layer has been fabricated and is being illuminated according to an embodiment of the present disclosure;

FIG. 7 is a schematic structural view illustrating a bottom gate type thin film transistor after a patterned photoresist layer has been formed according to an embodiment of the present disclosure;

FIG. 8 is a schematic structural view illustrating a bottom gate type thin film transistor after a photoresist layer in a second region has been removed according to an embodiment of the present disclosure;

FIG. 9 is a schematic structural view illustrating a bottom gate type thin film transistor after a gate metal film layer corresponding to a second region has been removed according to an embodiment of the present disclosure;

FIG. 10 is a schematic structural view illustrating a bottom gate type thin film transistor after the thickness of a gate metal film corresponding to a second region has been halved according to an embodiment of the present disclosure;

FIG. 11 is a schematic structural view illustrating a bottom gate type thin film transistor after a remaining photoresist layer has been removed according to an embodiment of the present disclosure;

FIG. 12 is a schematic structural view illustrating a bottom gate type thin film transistor after a gate has been formed according to an embodiment of the present disclosure; and

FIG. 13 is a schematic structural view of an array substrate provided by an embodiment of the present disclosure.

### DETAILED DESCRIPTION

Implementations of embodiments of the present disclosure will be described in detail below with reference to the accompanying drawings. It is to be noted that, throughout the disclosure, the same or similar reference numerals are used to refer to the same or similar elements or elements having the same or similar functions. The embodiments described below with reference to the accompanying drawings are illustrative and intended to interpret the present disclosure only, which shall not be construed as limiting the present disclosure.

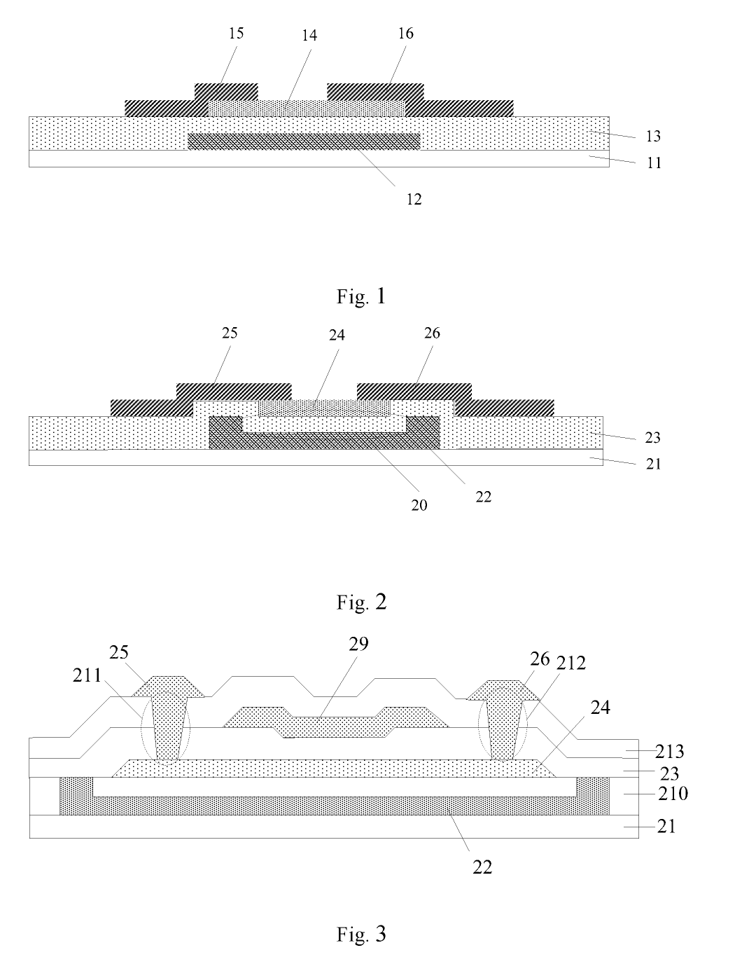

FIG. 1 illustrates a typical thin film transistor. As shown in FIG. 1, the thin film transistor comprises a gate 12 disposed on a base substrate 11, a gate insulating layer 13 disposed on the gate 12, an active layer 14 disposed on the gate insulating layer 13, and a source 15 and a drain 16 disposed on the active layer 14. In order to prevent the thin film transistor from generating excessive leakage current under illumination of a backlight, the thin film transistor is typically designed as a bottom gate structure in which the active layer 14 is shielded by the gate 12 to avoid photo-induced leakage current. However, this design cannot completely block all of the light from the backlight. For example, light from the backlight may still be incident on the active layer after being reflected and refracted, which increases the probability of generation of electron-hole pairs by means of illumination, and further generates photo-induced leakage current. It can be seen that the structure of the thin film transistor cannot effectively reduce the leakage current, and therefore the thin film transistor still has a large leakage current, which in turn causes a resultant display panel to be prone to involve crosstalk and splash screen defects.

FIG. 2 schematically illustrates a thin film transistor according to an embodiment of the present disclosure. Referring to FIG. 2, the thin film transistor comprises: a light shielding layer 22 disposed on a base substrate 21, and an active layer 24 disposed on the light shielding layer 22. The light shielding layer 22 is provided with a groove 20 on a side facing the active layer 24, wherein an orthographic projection of the active layer 24 on the base substrate 21 is located within an orthographic projection of a bottom surface of the groove 20 on the base substrate 21.

In embodiments of the present disclosure, the groove 20 is disposed on a side of the light shielding layer facing the active layer, and the orthographic projection of the active layer 24 on the base substrate 21 is located within the orthographic projection of the bottom surface of the groove 20 on the base substrate 21, so that the light shielding layer 22 can play a similar role as a shade to prevent light generated by a backlight from illuminating the active layer 24 after being reflected or refracted, which can thus minimize the leakage current generated by illumination, greatly improve the characteristics of the thin film transistor, and avoid occurrence of crosstalk and splash screen defects in the display panel resulting from excessive leakage current of the thin film transistor, thereby improving the display quality.

Upon implementation, the thin film transistor provided by embodiments of the present disclosure may be a bottom gate type thin film transistor or a top gate type thin film transistor. For a bottom gate type thin film transistor, the light shielding layer in embodiments of the present disclosure may be a light shielding or light absorbing material such as a dark resin, or the gate may directly serve as the light shielding layer, that is, a groove is disposed on a side of the gate facing the active layer. For a top gate type thin film transistor, the light shielding layer thereof may be a separate film layer other than the gate. Specifically, a groove may be disposed on a side of the light shielding layer facing the active layer to effectively block illumination of light from a backlight. The thin film transistors of the two structures are exemplified below by way of specific embodiments.

In an exemplary embodiment, as shown in FIG. 2, the thin film transistor is a bottom gate type thin film transistor, and the gate serves as the light shielding layer 22. The bottom gate type thin film transistor further comprises a gate insulating layer 23 disposed between the light shielding layer 22 and the active layer 24, and a source 25 and a drain 26 disposed on the active layer 24.

It is to be noted that, in such an embodiment, when the gate is used as the light shielding layer, the gate itself needs to include a light shielding material. For example, material of the gate may specifically be Mo/Al, Mo/Nd or Al/Nd.

In another exemplary embodiment, the thin film transistor is a top gate type thin film transistor, as shown in FIG. 3. The top gate type thin film transistor further comprises a passivation layer 210 disposed between the light shielding layer 22 and the active layer 24, a gate insulating layer 23 disposed on the active layer 24, a gate 29 disposed on the gate insulating layer 23, an interlayer insulating layer 213 disposed on the gate 29, and a source 25 and a drain 26 disposed on the interlayer insulating layer 213. The source 25 is connected to the active layer 24 through a first via hole 211, and the drain 26 is connected to the active layer 24 through a second via hole 212.

For the top gate type thin film transistor, the material of the light shielding layer may be a black resin.

In an exemplary embodiment, in order to enable the light shielding layer to more effectively block light from a backlight, the groove has an opening depth of from 1000 Å to 10000 Å. If the light shielding layer is a metal, particularly, the opening depth of the groove may be 1700 Å. If the light shielding layer is made of a black matrix material, the opening depth of the groove may be 5000 Å to 7500 Å.

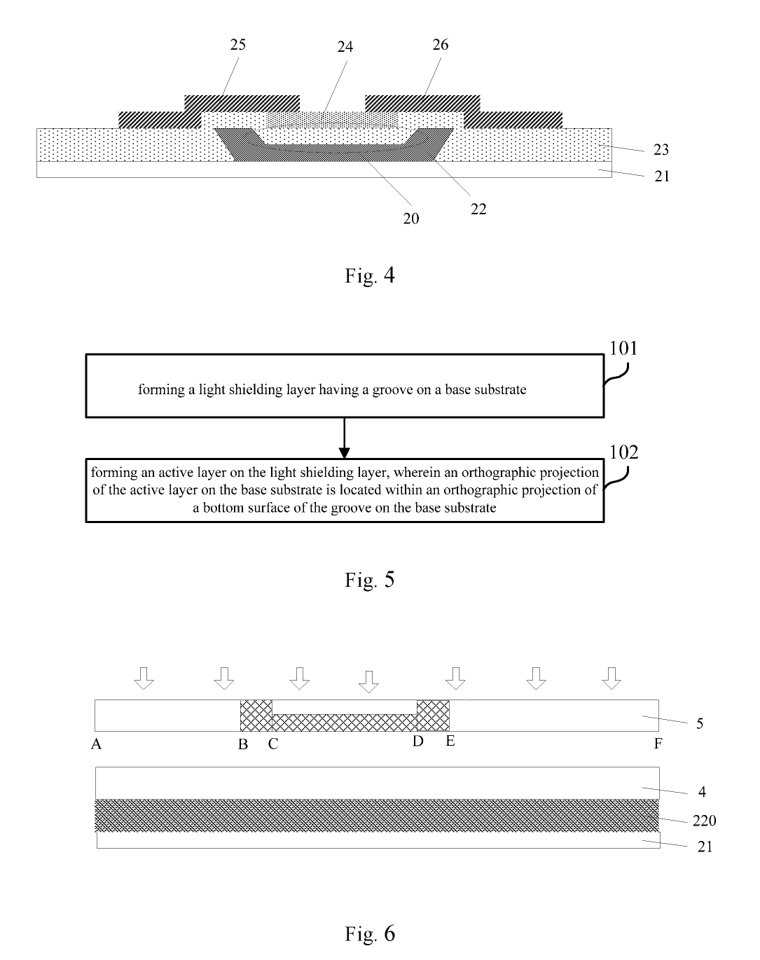

In an exemplary embodiment, an angle between an inner sidewall of the groove and the bottom thereof is greater than or equal to 90°. Specifically, for example, a sectional pattern of the opening of the groove 20 in a direction perpendicular to a plane direction of the base substrate may be a rectangle or an inverted trapezoid as shown in FIGS. 2 and 4, respectively.

An embodiment of the present disclosure further provides an array substrate comprising any of the thin film transistors described above.

An embodiment of the present disclosure further provides a display panel comprising a backlight, and any of the array substrates described above, wherein the array substrate is disposed on a light exit side of the backlight.

An embodiment of the present disclosure further provides a manufacturing method of a thin film transistor. As shown in FIG. 5, the manufacturing method comprises: at step 101, forming a light shielding layer having a groove on a base substrate, and at step 102, forming an active layer on the light shielding layer, wherein an orthographic projection of the active layer on the base substrate is located within an orthographic projection of a bottom surface of the groove on the base substrate.

In an exemplary embodiment, said forming a light shielding layer having a groove on a base substrate specifically comprises: forming a first film layer on the base substrate; forming, on the first film layer, a patterned photoresist layer having regions of different thicknesses by means of a halftone mask, wherein the patterned photoresist layer comprises a first region and a second region, the second region has a thickness smaller than that of the first region, and the orthographic projection of the bottom surface of the groove on the base substrate completely overlaps that of the second region on the base substrate; removing a portion of the first film layer that is not covered by the patterned photoresist layer; removing a photoresist layer in the second region; thinning a portion of the first film layer corresponding to the second region; and removing the remaining photoresist layer.

To simplify the manufacturing process, the groove may be formed by a halftone mask process. Said thinning a portion of the first film layer corresponding to the second region comprises: etching the first film layer corresponding to the second region for a preset duration so that the thickness of the first film layer corresponding to the second region is halved.

In order to explain in more detail the manufacturing method of a thin film transistor as provided by an embodiment of the present disclosure, description below is made with reference to FIGS. 6 to 12 based on an example in which the thin film transistor is a bottom gate type thin film transistor and the gate serves as a light shielding layer. It is to be noted that the concept of the present disclosure is also applicable to a top gate type thin film transistor.

Firstly, a gate metal film 220 is deposited on a base substrate 21 by, for example, a magnetron sputtering method, and a photoresist layer 4 is coated on the gate metal film 220 as shown in FIG. 6. Description below is made based on an example in which the photoresist is a positive photoresist. It is to be noted, however, that a negative photoresist may be employed in other embodiments of the present disclosure. The base substrate may be a glass substrate.

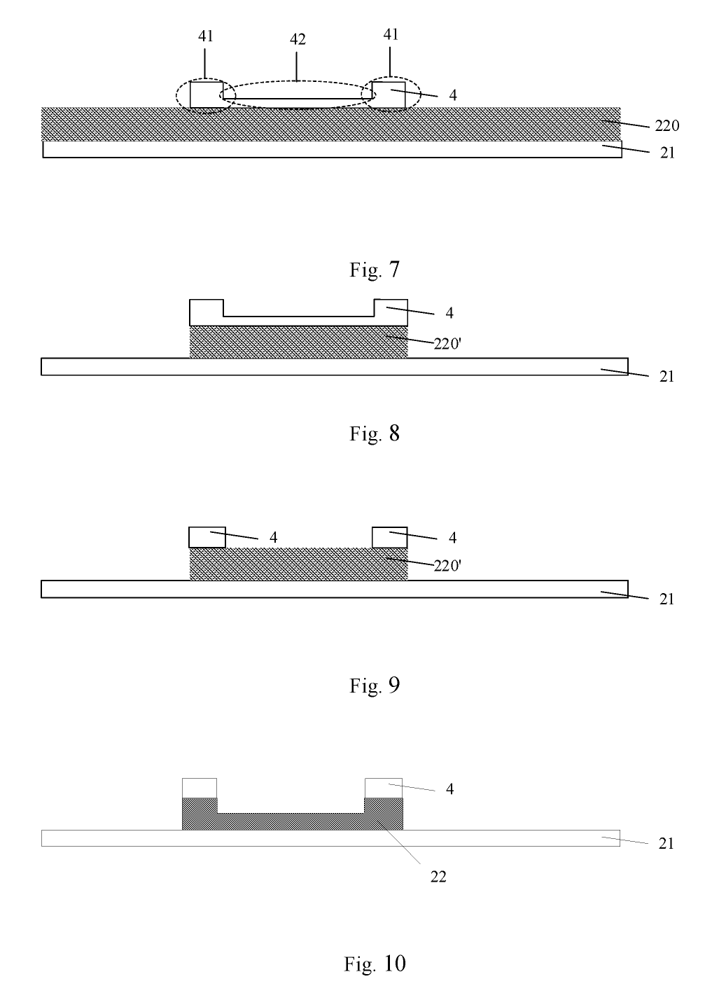

Then, the photoresist layer 4 is subjected to exposure and development using a halftone mask. An AB region and an EF region of a mask 5 are transparent regions, a BC region and a DE region are opaque regions, and a CD region is a semi-transmissive region, as shown in FIG. 6. After development, the photoresist corresponding to the transparent regions of the mask 5 is removed, the photoresist corresponding to the semi-transmissive region of the mask 5 is partially retained, and the photoresist corresponding to the opaque regions of the mask 5 is completely retained, forming a patterned photoresist layer 4 having a thickness smaller in a second region 420 than in a first region 41, as shown in FIG. 7.

Next, a portion of the gate metal film 220 not covered by the photoresist is removed by a wet etching process, and a portion of the gate metal film 220 corresponding to the patterned photoresist layer 4 is retained to form a light shielding material layer 220′, as shown in FIG. 8.

Then, the photoresist layer 4 in the second region 42 is removed by a dry etching process, as shown in FIG. 9.

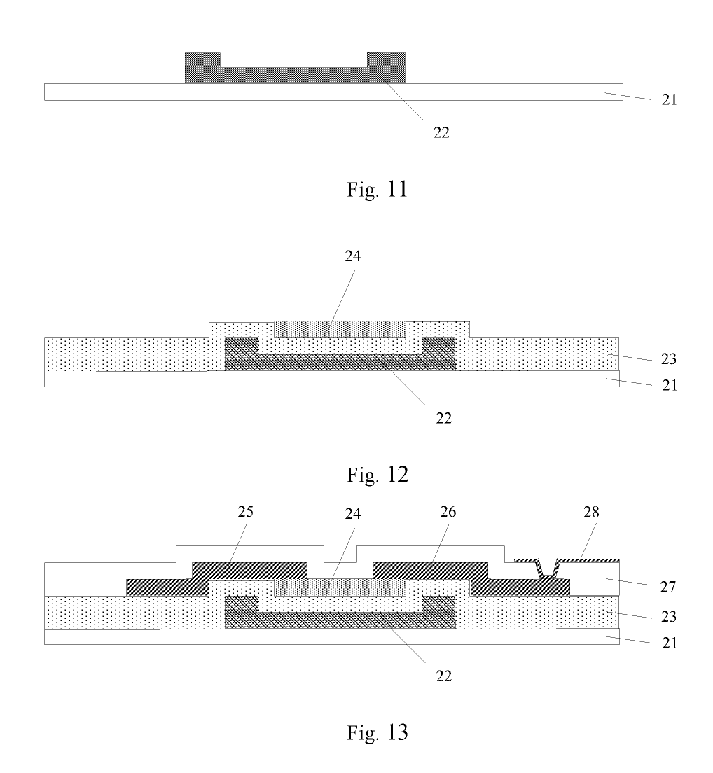

Next, etching time is controlled to thin the light shielding material layer 220′ corresponding to the second region 42 by a dry or wet etching process, as shown in FIG. 10. In particular, the thickness of the light shielding material layer 220′ corresponding to the second region 42 can be halved.

Finally, the remaining photoresist layer 4 is removed using a lift-off process to obtain a final light shielding layer 22, as shown in FIG. 11.

Further, the above manufacturing method may further comprise: obtaining a gate insulating layer 23 and an active material layer by a gas deposition method, and patterning the active material layer to obtain an active layer 24 so that an orthographic projection of the active layer 24 on the base substrate 21 is located within that of the bottom surface of the groove on the base substrate 21, as shown in FIG. 12.

In addition, the above manufacturing method may further comprise forming a source 25 and a drain 26 on the active layer 24, and forming an insulating protective layer 27 and a pixel electrode 28 on the source 25 and the drain 26 to obtain a final array substrate, as shown in FIG. 13.

In embodiments of the present disclosure, a groove is disposed on a side of the light shielding layer facing the active layer, and the orthographic projection of the active layer on the base substrate is located within the orthographic projection of the bottom surface of the groove on the base substrate, so that the light shielding layer can play a similar role as a shade to prevent light generated by a backlight from being reflected or refracted to the active layer, which can thus minimize the leakage current generated by illumination, greatly improve the characteristics of a TFT device, and further avoid occurrence of crosstalk and splash screen defects in the display panel resulting from excessive leakage current of the thin film transistor, thereby improving the display quality.

Obviously, those skilled in the art can make various modifications and variations to the present disclosure without departing from the spirit and scope thereof. In this way, if these modifications and variations to the present disclosure pertain to the scope of the claims of the present disclosure and equivalent technologies thereof, the present disclosure also intends to encompass these modifications and variations.

1. A thin film transistor comprising:
a light shielding layer on a base substrate; and
an active layer on the light shielding layer,
wherein the light shielding layer comprises a groove on a side facing the active layer, and
wherein an orthographic projection of the active layer on the base substrate is within an orthographic projection of a bottom surface of the groove on the base substrate.

2. The thin film transistor according to claim 1, wherein the light shielding layer comprises a gate, and the thin film transistor further comprises:
a gate insulating layer between the light shielding layer and the active layer; and
a source and a drain on the active layer.

3. The thin film transistor according to claim 1, further comprising:
a passivation layer between the light shielding layer and the active layer;
a gate insulating layer on the active layer;
a gate on the gate insulating layer;
an interlayer insulating layer on the gate; and
a source and a drain on the interlayer insulating layer,
wherein the source is connected to the active layer through a first via hole, and the drain is connected to the active layer through a second via hole.

4. The thin film transistor according to claim 2, wherein the groove has an opening depth from 1000 Å to 10000 Å.

5. The thin film transistor according to claim 1,
wherein the light shielding layer comprises a metal, and
wherein the groove has an opening depth of approximately 1700 Å.

6. The thin film transistor according to claim 1,
wherein the light shielding layer comprises a black matrix material, and
wherein the groove has an opening depth of 5000 Å to 7500 Å.

7. The thin film transistor according to claim 1, wherein an angle between an inner sidewall of the groove and a bottom of the groove is not less than 90°.

8. An array substrate comprising the thin film transistor according to claim 1.

9. A display panel comprising a backlight, and the array substrate according to claim 8, wherein the array substrate is on a light exit side of the backlight.

10. A manufacturing method of a thin film transistor, comprising:
forming a light shielding layer on a base substrate, wherein the light shielding layer comprises a groove; and
forming an active layer on the light shielding layer,
wherein an orthographic projection of the active layer on the base substrate is within an orthographic projection of a bottom surface of the groove on the base substrate.

11. The manufacturing method according to claim 10, wherein said forming a light shielding layer on a base substrate comprises:
forming a first film layer on the base substrate;
forming, on the first film layer, a patterned photoresist layer comprising regions of different thicknesses using a halftone mask, wherein the patterned photoresist layer comprises a first region and a second region, wherein the second region has a second thickness that is smaller than a first thickness of the first region, and wherein the orthographic projection of the bottom surface of the groove on the base substrate completely overlaps an orthographic projection of the second region on the base substrate;
removing a portion of the first film layer that is not covered by the patterned photoresist layer;
removing the photoresist layer in the second region;
thinning a portion of the first film layer corresponding to the second region; and
removing a remaining photoresist layer.

12. The manufacturing method according to claim 11, wherein said thinning a portion of the first film layer corresponding to the second region comprises:
etching the portion of the first film layer corresponding to the second region for a preset duration so that a third thickness of the portion of the first film layer corresponding to the second region is half of a fourth thickness prior to the etching.

13. The thin film transistor according to claim 3, wherein the groove has an opening depth from 1000 Å to 10000 Å.

14. The thin film transistor according to claim 2,
wherein the light shielding layer comprises a metal, and
wherein the groove has an opening depth of approximately 1700 Å.

15. The array substrate according to claim 8, wherein the light shielding layer comprises a gate, and the thin film transistor further comprises:
a gate insulating layer between the light shielding layer and the active layer; and
a source and a drain on the active layer.

16. The array substrate according to claim 8, further comprising:
a passivation layer between the light shielding layer and the active layer;
a gate insulating layer on the active layer;
a gate on the gate insulating layer;
an interlayer insulating layer on the gate; and
a source and a drain on the interlayer insulating layer,
wherein the source is connected to the active layer through a first via hole, and the drain is connected to the active layer through a second via hole.

17. The array substrate according to claim 15, wherein the groove has an opening depth from 1000 Å to 10000 Å.

18. The array substrate according to claim 8, wherein the light shielding layer comprises a metal, and the groove has an opening depth of approximately 1700 Å.

19. The array substrate according to claim 8, wherein the light shielding layer comprises a black matrix material, and the groove has an opening depth of 5000 Å to 7500 Å.

20. The array substrate according to claim 8, wherein an angle between an inner sidewall of the groove and a bottom of the groove is not less than 90°.
